(19) United States
(12) Patent Application Publication
(10) Pub. No.: US 2013/0206176 A1
(43) Pub. Date: Aug. 15, 2013

(54) Cleaning system and cleaning method

(71) Applicant: Kurita Water Industries Ltd., (US)

(72) Inventors: Minoru Uchida, Tokyo (JP); Tatsuo Nagai, Tokyo (JP)

(73) Assignee: Kurita Water Industries Ltd., Tokyo (JP)

(21) Appl. No.: 13/707,237

(22) Filed: Dec. 6, 2012

Related U.S. Application Data
(63) Continuation of application No. PCT/JP2011/062059, filed on May 26, 2011.

(30) Foreign Application Priority Data
Jun. 7, 2010 (JP) 2010-130573

(51) Int. Cl. H01L 21/02

(52) U.S. Cl. CPC H01L 21/02076
USPC 134/10; 134/108

(57) ABSTRACT

Provided is a cleaning system including an electrolysis unit that electrolyses a sulphuric acid solution, thereby generating persulphuric acid, an electrolytic solution storage unit that stores the electrolyzed sulphuric acid solution, a first circulation line that circulates the sulphuric acid solution between the electrolysis unit and the electrolytic solution storage unit, a cleaning device that cleans a material subject to cleaning by using the sulphuric acid solution containing the persulphuric acid, a heating unit that heats the sulphuric acid solution used for the cleaning device, a waste liquid storage unit that stores the sulphuric acid solution used by the cleaning device, a second circulation line that transports the sulphuric acid solution electrolyzed by the electrolysis unit via the heating unit to the cleaning device, and circulates the sulphuric acid solution used by the cleaning device for the cleaning via the waste liquid storage unit, and a third circulation line that transports the sulphuric acid solution electrolyzed by the electrolysis unit to the waste liquid storage unit without passing the sulphuric acid solution through the cleaning device, thereby circulating the sulphuric acid solution.

### TECHNICAL FIELD

The present invention relates to a cleaning system which can be preferably used for cleaning a resist attached to an electronic material such as a silicon wafer, and supplies a cleaning device for carrying out the cleaning of the resist or the like with a sulphuric acid solution containing persulphuric acid obtained by electrolyzing the sulphuric acid solution, and a cleaning method.

### BACKGROUND ART

A sulphuric acid electrolysis method of electrolyzing a sulphuric acid solution thereby generating persulphuric acid (peroxodisulphuric acid and peroxomonosulphuric acid; molecular persulphuric acid and ionic persulphuric acid), and carrying out cleaning by using the persulphuric acid as a cleaning liquid is known in the resist stripping process of the semiconductor manufacturing. The resist stripping progresses more efficiently as the temperature of the cleaning liquid increases in the resist stripping process. This is because, if the cleaning liquid produced by the sulphuric acid electrolysis method reaches a predetermined high temperature, the persulphuric acid in the cleaning liquid decomposes by itself, thereby generating sulphuric acid radical which has extremely powerful oxidizing property, and contributing to the cleaning.

The radical is short in life, and if the cleaning liquid is heated in an early stage, the self-decomposition of the persulphuric acid contained in the cleaning liquid becomes too early, and the radical is consumed without contributing to the cleaning. Moreover, if the cleaning liquid is slowly heated for a long period (such as approximately several minutes), the self-decomposition of the persulphuric acid and the decomposition of the sulphuric acid radical make progress in the course of heating, and the sulphuric acid concentration has already decreased when the temperature becomes high.

Moreover, as the method of cleaning an electronic material substrate and the like, there is a single wafer type in addition to a batch type. An object to be cleaned is fixed to a rotation stand, for example, and a chemical liquid is sprayed or is flown down by a small quantity at a time on the object while the rotation stand is rotating in the single wafer type. A degree of cleanliness of an electronic material substrate such as a wafer can be maintained higher in a single-wafer cleaning device compared with the batch cleaning. However, stricter characteristics are required for the chemical liquid used for the single-wafer cleaning device than those for the electrolyzed sulphuric acid solution used for the batch type cleaning device. Particularly, the cleaning for stripping a resist into which ion is implanted at a high density equal to or more than 1×10¹⁵ atoms/cm² requires a cleaning liquid having a higher persulphuric acid concentration and a higher liquid temperature.

The present inventors have proposed a cleaning system provided with a rapid heater assuming that the heating of the cleaning liquid needs to be carried out in a very short period immediately before the cleaning in view of these aspects (refer to Japanese Patent Application Laid-open No. 2010-60147).

The cleaning system circulates a sulphuric acid solution between an electrolysis reaction device and an electrolytic solution storage tank while the sulphuric acid is being electrolyzed, and a part of the sulphuric acid solution is taken out, is heated by the rapid heater, and is supplied to the cleaning device. Moreover, the sulphuric acid solution used for the cleaning in the cleaning device is once stored in a waste liquid storage tank as a waste liquid, thereby decomposing residual organic matters moved into the sulphuric acid solution. The sulphuric acid solution for which the residual organic matters have been decomposed in the waste storage tank is transported to the electrolytic solution storage tank, and is used again for the electrolysis. Particularly, the sulphuric acid solution is discharged immediately after the sulphuric acid solution comes in contact with a material to be cleaned in the single-wafer cleaning device, and there is thus not an enough time for the progress of the decomposition of the residual organic matters in the cleaning device. Thus, the necessity for the decomposition in the waste liquid storage tank is high. If the residual organic matters are not sufficiently decomposed in the waste liquid storage tank, contaminants are directly fed to the electrolysis reaction device, and cause contamination of the electrolysis reaction device and a decrease of electrolysis efficiency, and the like.

### CITATION LIST

### Patent Literature

Patent Literature 1: Japanese Patent Application Laid-Open No. 2010-60147

### SUMMARY OF INVENTION

### Problems to be Solved by the Invention

By the way, the single-wafer cleaning alternatively repeats a cleaning process and a cleaning subject material replacement process. While the electrolysis sulphuric acid solution is used for the cleaning in the cleaning process, the electrolysis sulphuric acid solution is not necessary in the cleaning subject material replacement process in the cleaning device, the supply of the sulphuric acid solution from the electrolytic solution storage tank to the rapid heater is stopped, and the entire quantity of the sulphuric acid discharged from the electrolytic solution storage tank is circulated between the electrolytic solution storage tank and the electrolysis device.

However, the waste cleaning liquid at the high temperature is not fed to the waste liquid storage tank in the cleaning subject material replacement process, the persulphuric acid is not supplied, and the persulphuric acid concentration gradually decreases. Moreover, the temperature in the tank gradually decreases. As a result, the decomposition of the residual resist is not sufficient in the cleaning subject material switching process. Further, there is a concern that the persulphuric acid concentration is low in the waste liquid storage tank, and the temperature is low in the tank, and the residual resist is thus insufficiently decomposed at an initial stage of the next cleaning process after the cleaning subject material is replaced. To address this problem, though such a configuration that the temperature is maintained high in the tank by heating the inside of the tank is conceivable, there poses such a problem that an independent heater or the like is necessary for that. Moreover, even if the heater is provided, the persulphuric acid is not supplied, the persulphuric acid concentration decreases as the time elapses after the switching to the cleaning subject material replacement process, and if the quantity of the residual resist is high, the persulphuric acid is insufficient, and it is suspected that the resist is not sufficiently decomposed.

The present invention is devised in view of the foregoing problems, and has an object to provide a cleaning system and a cleaning method which can decompose residual organic matters and the like in the waste liquid storage tank even when the cleaning is stopped, and can efficiently decompose the residual organic matters and the like contained in the waste cleaning liquid when the cleaning is resumed.

### Means for Solving by the Invention

In other words, a cleaning system according to the present invention includes an electrolysis unit that electrolyzes a sulphuric acid solution, thereby generating persulphuric acid, an electrolytic solution storage unit that stores the electrolyzed sulphuric acid solution, a first circulation line that circulates the sulphuric acid solution between the electrolysis unit and the electrolytic solution storage unit, a cleaning device that cleans a material subject to cleaning by using the sulphuric acid solution containing the persulphuric acid, a heating unit that heats the sulphuric acid solution used for the cleaning device, a waste liquid storage unit that stores the sulphuric acid solution used by the cleaning device, a second circulation line that transports the sulphuric acid solution electrolyzed by the electrolysis unit via the heating unit to the cleaning device, and circulates the sulphuric acid solution used by the cleaning device for the cleaning via the waste liquid storage unit, and a third circulation line that transports the sulphuric acid solution electrolyzed by the electrolysis unit to the waste liquid storage unit without passing the sulphuric acid solution through the cleaning device, thereby circulating the sulphuric acid solution.

Moreover, a cleaning method according to the present invention includes electrolyzing a sulphuric acid solution while circulating the sulphuric acid solution during cleaning, branching a part of the electrolyzed sulphuric acid solution, heating the branched part of the sulphuric acid solution, using the heated sulphuric acid solution for cleaning a material subject to cleaning, storing thereafter the sulphuric acid solution, thereby decomposing the material subject to cleaning, which has moved into the sulphuric acid solution, simultaneously circulating the stored sulphuric acid solution for the electrolysis, circulating the sulphuric acid solution while electrolyzing the sulphuric acid solution when the cleaning is stopped, simultaneously branching a part of the electrolyzed sulphuric acid solution, thereby supplying the branched part of the electrolyzed sulphuric acid solution to the stored sulphuric acid solution, and decomposing the material subject to cleaning which has moved into the sulphuric acid solution, and circulating the stored sulphuric acid solution for the electrolysis.

According to the present invention, the sulphuric acid solution can be circulated by the first circulation line between the electrolysis unit and the electrolytic solution storage unit, thereby continuously generating the persulphuric acid by the electrolysis.

Moreover, the sulphuric acid solution electrolyzed by the electrolysis unit is taken out by the second circulation line, is heated by the heating unit, and then is supplied to the cleaning device. The sulphuric acid solution used for the cleaning is circulated by the second circulation line. On this occasion, the sulphuric acid solution is once stored in the waste liquid storage unit, residual organic matters and the like are decomposed, and, then, the sulphuric acid solution is used again for the electrolysis. The outlet location on the second circulation line may be any of a liquid outlet side of the electrolysis unit, the first circulation line, and the electrolytic solution storage unit, and a location for the circulation flow may be any of the liquid outlet side of the electrolysis unit, the first circulation line, and the electrolytic solution storage unit. For stable outlet and circulation flow, the outlet from the electrolytic solution storage unit and the circulation flow to the electrolyte storage unit are desired.

Moreover, the sulphuric acid solution electrolyzed by the electrolysis unit is taken out by the third circulation line, and is supplied to the waste liquid storage unit without passing through the cleaning device. As result, when the supply of the sulphuric acid solution from the cleaning device is stopped, the persulphuric acid is supplied to the waste liquid storage unit, and the residual organic matters and the like contained in the sulphuric acid solution stored in the waste liquid storage unit is efficiently decomposed. Moreover, when the sulphuric acid solution used for the cleaning from the cleaning device is supplied via the second circulation line to the waste liquid storage unit, the sulphuric acid solution may be supplied by the third circulation line. As a result, even if the concentration of the residual organic matters is particularly high in the waste liquid storage unit, the efficient decomposition can be carried out by supplying a large quantity of the persulphuric acid.

It should be noted that the third circulation line preferably transports the sulphuric acid solution via the heating unit to the waste liquid storage unit. As a result, even if the cleaning is stopped, the heated sulphuric acid solution is supplied to the waste liquid storage tank, thereby efficiently decomposing the residual organic matters. As a result, the temperature of the stored sulphuric acid solution is prevented from decreasing without providing a heater or the like in the waste liquid storage unit.

The sulphuric acid solution transported by the third circulation line can be heated to a temperature lower than the temperature used for the cleaning, and can be supplied to the waste liquid storage unit. As a result, the oxidizing capability is maintained, and the residual organic matters in the solution can be efficiently heated. On this occasion, the heated sulphuric acid solution can be supplied so that the temperature of the waste liquid storage unit is 120-160° C. It should be noted that the heated sulphuric acid solution is more preferably supplied so that the temperature of the waste liquid storage unit is 130-160° C.

Moreover, when the sulphuric acid solution in the waste liquid storage unit is circulated by the second circulation line and the third circulation line, the sulphuric acid solution is preferably cooled by a second cooling unit. As a result, it is possible to prevent the temperature of the sulphuric acid solution in the electrolytic solution storage unit and the like from increasing, thereby causing the self-decomposition of the persulphuric acid to progress, causing the temperature to exceed a temperature proper for the electrolysis, and causing a load imposed by cooling in the electrolysis unit side to increase.

The second circulation line and the third circulation line may be selectively used. In this case, when the second circulation line is used to supply the sulphuric acid solution to the cleaning device, the third circulation line is stopped, and the cleaning in the cleaning device is stopped for replacing the cleaning subject material, the second circulation line is stopped, and the sulphuric acid solution is supplied via the third circulation line to the waste liquid storage unit. The selective use can be realized by operating a on-off valve or a selector valve provided on the line.

Moreover, the second circulation line and the third circulation line can simultaneously be used always or according to necessity. As a result, the persulphuric acid concentration in the waste liquid storage unit can be increased, thereby increasing the decomposition capability.

Moreover, the second circulation line and the third circulation line may have a shared part. Thus, if the second circulation line and the third circulation line are selectively used, the part of the circulation line is used as the second circulation line when the cleaning is carried out, and is used as the third circulation line when the cleaning is stopped.

It should be noted that the electrolysis unit electrolyzes the sulphuric acid solution, thereby generating the persulphuric acid which increases the cleaning effect. As the temperature of the solution decreases, the generation efficiency of the persulphuric acid increases in this electrolysis. Thus, the electrolysis temperature for generating the persulphuric acid is preferably 80° C. or less. If the temperature exceeds the above-described temperature range, the electrolysis efficiency significantly decreases. On the other hand, if the temperature is too low, the loss of electrode becomes high. Thus, the temperature is preferably 40° C. or more.

In order to obtain a proper temperature, the sulphuric acid solution from the electrolytic solution storage unit to the electrolysis unit may be cooled by a first cooling unit.

The electrolysis is carried out while a anode and a cathode are paired in the electrolysis unit. Materials for these electrodes are not limited to specific materials according to the present invention. However, if platinum which is generally widely used is used for the anode of the electrolysis unit of the present invention, there pose such problems that the persulphuric acid is not effectively produced, and that the platinum is dissolved. In contrast, an electrically conductive diamond electrode can efficiently produce persulphuric acid, and the wear of the electrode is small. Thus, at least the anode for generating the persulphuric acid out of the electrodes of the electrolysis unit is preferably constituted by an electrically conductive diamond electrode, and both the anode and the cathode are more preferably constituted by electrically conductive diamond electrodes. As the electrically conductive diamond electrode, an electrode which is made by using a semiconductor material such as a silicon wafer as a substrate, and synthesizing an electrically conductive diamond thin film on a wafer surface, and a self-stand type conductive polycrystalline diamond which is deposited and synthesized in a plate form can be mentioned. Moreover, electrically conductive diamond laminated on a metal substrate such as Nb, W, and Ti may be used. It should be noted that the conductive diamond thin film is produced by doping a predetermined quantity of boron or nitrogen thereby imparting electric conductivity when the diamond thin film is synthesized, and a diamond thin film is usually doped with boron. If the doped quantity is too small, a technical meaning is not provided, and if the doped quantity is too large, the dope effect saturates, and doping in a range of 50-20,000 ppm with respect to the carbon quantity of the diamond thin film is proper.

The temperature of the sulphuric acid solution in the electrolysis solution storage unit is preferably 50-90° C. The sulphuric acid solution in the electrolysis solution storage unit is transported to the electrolysis unit, and, if the temperature is high, cooling for the electrolysis is necessary for the electrolysis, the load imposed by the cooling is high, and the temperature is preferably 90° C. or less. If the temperature is decreased, the electrode loss is suspected in the electrolysis unit, and the temperature of the sulphuric acid solution in the electrolysis solution storage unit is preferably 50° C. or more.

Moreover, the heating unit preferably heats the sulphuric acid solution for the cleaning so that the temperature of the sulphuric acid solution is 150-220° C. for the single wafer type. If the heated temperature is less than 150° C., the oxidizing capability brought about by the self-decomposition of the persulphuric acid is not sufficiently provided. On the other hand, if the temperature of the sulphuric acid is excessively high, the decomposition speed of the persulphuric acid becomes too fast, the cleaning capability decreases on the contrary, and the temperature is preferably equal to or less than 220° C. The heating unit may be constituted by one heater and the like, as well as by multiple heaters and the like. For example, the heating unit may be constituted by a preheater on an upstream side which preheats the sulphuric acid solution, and a rapid heater on a downstream side which rapidly heats the sulphuric acid solution. For example, the sulphuric acid solution is heated to approximately 90° C.-120° C. by the preheater, and is then rapidly heated, thereby reducing a load imposed on the rapid heater. If the temperature by the preheating is less than 90° C., the effect of reducing the heating load on the rapid heater is small, if the temperature exceeds 120° C., the self-decomposition of the persulphuric acid progresses, sufficient oxidizing capability cannot be obtained for the cleaning, and the above-described temperature range is thus preferable as the preheating.

The sulphuric acid solution used in the cleaning system is preferably 85 mass % or more in the sulphuric acid concentration. If the sulphuric acid concentration is less than 85 mass %, and even if the persulphuric acid concentration is high, the resist stripping capability decreases in the cleaning device. On the other hand, if the sulphuric acid concentration exceeds 96 mass %, a current efficiency decreases in the electrolysis process, and the concentration is preferably 96 mass % or less.

Though the cleaning can be carried out for various cleaning subject materials according to the present invention, the present invention is preferable for applications for carrying out the cleaning process intended for an electronic material substrate such as a silicon wafer, a glass substrate for liquid crystal, and a photomask substrate. More specifically, the present invention can be used for a stripping process for an organic compound such as a resist residual attached to a semiconductor substrate. Moreover, the present invention can be used for a process for removing foreign matters such as particles and metals attached to a semiconductor substrate.

Moreover, the present invention can be used for a process of cleaning and stripping contaminants attached to a substrate such as a silicon wafer using a high-concentration sulphuric acid solution, and is preferably used as a system which omits preprocessing process such as the ashing process, and produces the persulphuric acid on site by the electrolysis unit in order to increase the resist stripping/oxidizing effect, and repeatedly uses the sulphuric acid solution without requiring addition of a chemical liquid such as hydrogen peroxide and ozone from the outside.

### Effects of the Invention

As described above, according to the present invention, the electrolysis unit that electrolyzes a sulphuric acid solution, thereby generating persulphuric acid, the electrolytic solution storage unit that stores the electrolyzed sulphuric acid solution, the first circulation line that circulates the sulphuric acid solution between the electrolysis unit and the electrolytic solution storage unit, the cleaning device that cleans a material subject to cleaning by using the sulphuric acid solution containing the persulphuric acid, the heating unit that heats the sulphuric acid solution used for the cleaning device, the waste liquid storage unit for storing the sulphuric acid solution used by the cleaning device, the second circulation line that transports the sulphuric acid solution electrolyzed by the electrolysis unit via the heating unit to the cleaning device, and circulates the sulphuric acid solution used by the cleaning device for the cleaning via the waste liquid storage unit, and the third circulation line that transports the sulphuric acid solution electrolyzed by the electrolysis unit to the waste liquid storage unit without passing through the cleaning device, thereby circulating the sulphuric acid solution, are provided, and the persulphuric acid can be supplied to the waste liquid storage unit, thereby promoting the decomposition of the residual organic matters and the like in the sulphuric acid solution. Further, when the cleaning is stopped due to a switching process for a material subject to cleaning or the like, the sulphuric acid solution having a high oxidizing property is continuously supplied to the waste liquid storage unit by switching the supply of the sulphuric acid solution to operate the third circulation line, and the residual resist and the like can surely be decomposed.

### BRIEF DESCRIPTION OF THE DRAWINGS

FIG. 1 is a flowchart showing a cleaning system according to an embodiment of the present invention.

### MODE FOR CARRYING OUT THE INVENTION

### First Embodiment

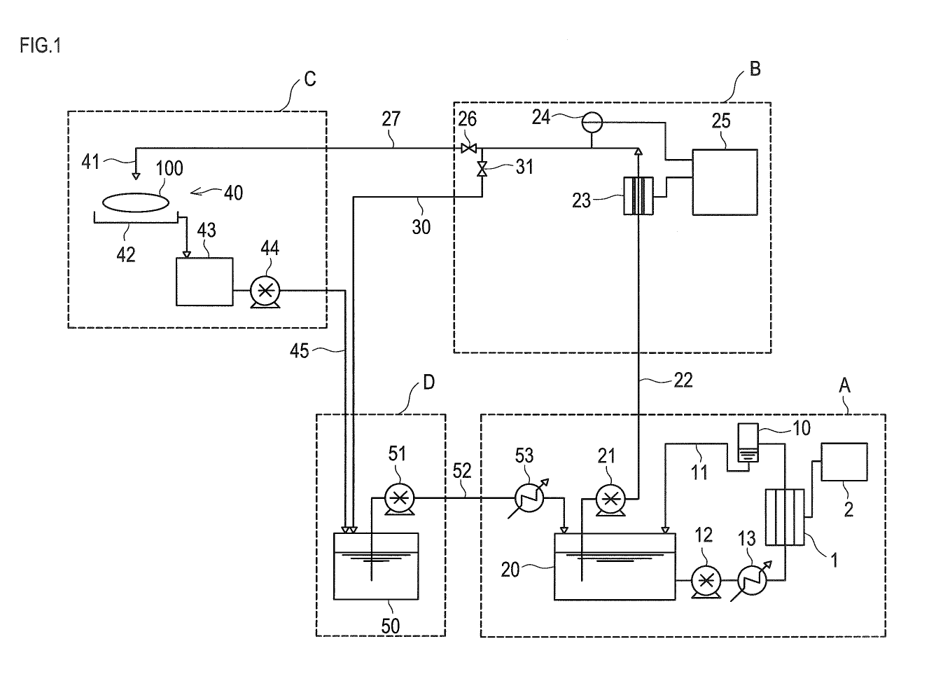

A description will now be given of an embodiment of a cleaning system according to the present invention referring to FIG. 1.

An electrolysis device 1 corresponding to an electrolysis unit of the present invention is the non-diaphragm type, and an anode and a cathode (not shown) which are constituted by a diamond electrode are not separated by a diaphragm, and are arranged inside, and a DC power supply 2 is connected to both the electrodes. It should be noted that the electrolysis device may be constituted by a non-diaphragm type electrolysis device according to the present invention.

An electrolytic solution storage tank 20 corresponding to an electrolytic solution storage unit according to the present invention is connected for circulating and passing a liquid via a first circulation line 11 to the electrolysis device 1. A gas/liquid separation tank 10 is interposed on a return side of the first circulation line 11. The gas/liquid separation tank 10 stores a sulphuric acid solution containing gas, separates the gas in the sulphuric acid solution, and discharges the gas to the outside of the system, a known gas/liquid separation tank can be used, and a configuration thereof is not limited according to the present invention as long as the gas/liquid separation can be provided.

Moreover, a circulation pump 12 which circulates the sulphuric acid solution, and a cooler 13 which cools the sulphuric acid solution are interposed on a supply side of the first circulation line 11. The cooler 13 corresponds to a first cooling unit according to the present invention, and can be any cooler as long as the cooler cools the sulphuric acid solution, thereby enabling electrolysis at a liquid temperature of 40-80° C., and the configuration thereof is not specifically limited according to the present invention.

Moreover, a liquid transport line 22 is connected via a supply pump 21 to the electrolytic solution storage tank 20.

An electrolysis unit A is constituted by the electrolysis device 1, the DC power supply 2, the first circulation line 11, the circulation pump 12, the cooler 13, the gas/liquid separation tank 10, the electrolytic solution storage tank 20, and a cooler 53, which is described later.

Though the description has been given of the electrolysis unit including both the gas/liquid separation tank 10 and the electrolytic solution storage tank 20, the electrolysis unit may have an electrolytic solution storage tank also serving as the gas/liquid separator.

A rapid heater 23 is interposed in a liquid transport direction of the liquid transport line 22. The liquid transport line 22 is connected to an on-off valve 26 on a downstream side of the rapid heater 23. A liquid transport line 27 is connected to the other end side of the on-off valve 26, and a liquid transport distal end side of the liquid transport line 27 is connected to a single-wafer cleaning device 40.

The rapid heater 23 corresponds to a heating unit of the present invention, has a pipeline made of quartz, and rapidly heats the sulphuric acid solution by a near-infrared heater, for example, in a single pass manner so that the liquid temperature of 150-220° C. is provided at an entrance of the cleaning device 40.

Moreover, a liquid temperature measurement device 24 for measuring the temperature of the transported sulphuric acid solution is provided on the liquid transport line 22 downstream of the rapid heater 23, and a measurement result of the liquid temperature measurement device 24 is output to a power supply unit 25 including the DC power supply. The power supply unit 25 supplies the rapid heater 23 with an electric power of a predetermined power supply quantity, receives the measurement result by the liquid temperature measurement device 24, and controls the power supply quantity to the rapid heater 23 so that the liquid temperature is at a predetermined temperature.

The rapid heater 23, the liquid temperature measurement device 24, and the power supply unit 25 construct a rapid heating unit B.

A liquid transport line 30 branches from the liquid transport line 22 upstream of the on-off valve 26, and a on-off valve 31 is interposed on the liquid transport line 30. A liquid transport leading end side of the liquid transport line 30 is connected to a waste liquid storage tank 50 described later.

The single-wafer cleaning device 40 includes a nozzle 41 directed to an electric material substrate 100, which is a material subject to cleaning, which has been brought therein, and includes a rotation stand 42 for rotating the electronic material substrate 100 on which the sulphuric acid solution as a cleaning liquid is sprayed by the nozzle 41, or the sulphuric acid solution flows down by a small quantity at a time. Further, a sulphuric acid solution collection unit 43 which collects droplets of the sulphuric acid solution used for the cleaning is provided, and a circulation flow line 45 on which a first circulation flow pump 44 is interposed is connected to the sulphuric acid solution collection unit 43.

The cleaning device 40, the nozzle 41, the rotation stand 42, the sulphuric acid solution collection unit 43, and the first circulation flow pump 44 construct a cleaning unit C.

Though a description is given of the embodiment while it is assumed that the cleaning device is of the single wafer type, the type of the cleaning device is not limited to the single wafer type according to the present invention, and the cleaning device may be a batch-type cleaning device.

The liquid transport leading end side of circulation flow line 45 is connected to the waste liquid storage tank 50 which stores the sulphuric acid solution used for the cleaning. The waste liquid storage tank 50 corresponds to a waste liquid storage unit of the present invention. A circulation flow line 52 is connected via a second circulation flow pump 51 to the waste liquid storage tank 50, a cooler 53 corresponding to a second cooling unit of the present invention is interposed on the circulation flow line 52, and a liquid transport leading end portion of the circulation flow line 52 is connected to the electrolytic solution storage tank 20.

The waste liquid storage tank 50 and the second circulation flow pump 51 constitute a waste liquid storage unit D.

The liquid transport line 22, the liquid transport line 27, the circulation flow line 45, and the circulation flow line 52 construct a second circulation line according to the present invention, and the liquid transport line 22, the liquid transport line 30, and the circulation flow line 52 construct a third circulation line according to the present invention.

Thus, the second circulation line and the third circulation line are constituted by sharing the liquid transport line 22 and the circulation flow line 52.

A description will now be given of an operation of the cleaning system constituted as described above.

A sulphuric acid solution at 85-96 mass % in sulphuric acid concentration and 50-90° C. in liquid temperature is stored in the electrolyte solution storage tank 20. The sulphuric acid solution is transported by the circulation pump 12, is adjusted in temperature to a proper temperature for the electrolysis (40-80° C.) by the cooler 13, and is introduced into a liquid inlet side of the electrolysis device 1. An electric power is supplied between the anode and the cathode by the DC power supply 2 in the electrolysis device 1, and the sulphuric acid solution introduced into the electrolysis device 1 is electrolyzed. Oxidizing substance including persulphuric acid are generated, and the oxygen gas is generated on the anode side, and the hydrogen gas is generated on the cathode side by the electrolysis in the electrolysis device 1. The oxidizing substance and the gases are transported via the first circulation line 11 in a state in which the oxidizing substance and the gases are mixed with the sulphuric acid solution to the gas/liquid separation tank 10, and the gases are separated. The gases are discharged to the outside of the system, and are safely processed by a catalyst device (not shown) or the like.

The sulphuric acid solution from which the gases are separated by the gas/liquid separation tank 10 contains the persulphuric acid, is returned to the electrolytic solution storage tank 20 via the return side of the first circulation line 11, is then repeatedly transported to the electrolysis device 1, and is increased in concentration of the persulphuric acid by the electrolysis. If the concentration of the persulphuric acid reaches a proper degree, a part of the sulphuric acid solution in the electrolytic solution storage tank 20 is transported via the liquid transport line 22 to the rapid heater 23 by the liquid transport pump 21.

The sulphuric acid solution containing the persulphuric acid is heated by a near-infrared heater while passing through a flow passage in the rapid heater 23. On this occasion, rapid heating is carried out so that the sulphuric acid solution has a liquid temperature in a range from 150° C.-220° C. when the sulphuric acid solution is supplied to the cleaning device 40. The heated temperature can be approximately the same as the temperature for use by arranging the rapid heater 23 close to the cleaning device 40.

The heated sulphuric acid solution containing the persulphuric acid is transported via the on-off value 26 to the liquid transport line 27, is supplied to the single-wafer cleaning device 40 by the liquid transport line 27, and is used for cleaning the electronic material substrate 100.

On this occasion, the on-off valve 31 is closed, and the sulphuric acid solution is not supplied to the liquid transport line 30.

The sulphuric acid solution is adjusted in flow rate so that a liquid passage time from the entrance of the rapid heater 23 to the use of the cleaning device 40 is preferably less than one minute upon the liquid transport. A proper flow rate is 500-2000 ml/min in the single-wafer cleaning device 40, and the length of a flow passage, a flow passage cross sectional area of the rapid heater 23, line lengths and flow passage cross sectional areas of the liquid transport lines 22 and 27 downstream thereof, and the like are set so that the liquid transport time is less than one minute at this flow rate.

The electronic material substrate 100 such as a silicon wafer provided with a resist ion-implanted at a high concentration equal to or more than 1×10¹⁵ atoms/cm², for example, is subject to the cleaning in the cleaning device 40. Contaminants such as the resist on the electronic material substrate 100 are efficiently stripped and removed by spraying or flowing down, by a small quantity at a time, the sulphuric acid solution containing the persulphuric acid at the high temperature from the nozzle 41, thereby brining the sulphuric acid solution in contact with the electronic material substrate 100 while the electronic material substrate 100 is rotated on the rotation stand 42.

The sulphuric acid solution used for the cleaning is collected by the sulphuric acid solution collection unit 43, is then discharged from the cleaning device 40, is transported by the first circulation flow pump 44 via the circulation flow line 45 to the waste liquid storage tank 50, and is stored in the waste liquid storage tank 50. The sulphuric acid solution contains the residual organic matters such as the resist resulting from the cleaning by the cleaning device 40, and the residual organic matters are oxidized and decomposed by the oxidizing substance contained in the sulphuric acid solution while the sulphuric acid is being stored in the waste liquid storage tank 50. It should be noted that a storage time of the sulphuric acid solution in the waste liquid storage tank 50 can be arbitrarily adjusted depending on a contained quantity of the residual organic matters and the like. On this occasion, the sulphuric acid solution which is at the high temperature and contains the persulphuric acid is continuously supplied from the cleaning device 40, and the waste liquid storage tank 50 is maintained to a proper temperature.

The sulphuric acid solution in which the contained residual organic matters have been decomposed in the waste liquid storage tank 50 is circulated by the second circulation flow pump 51 via the cooler 53 interposed on the circulation flow line 52 to the electrolytic liquid storage tank 20. A filter may be interposed on the downstream side of the waste liquid storage tank 50 and on the upstream side of the cooler 53. As a result, SS (suspended solid) which is not processed by the waste liquid storage tank 50 is caught and removed by the filter in the sulphuric acid solution.

Moreover, if the sulphuric acid solution at a high temperature is circulated to the electrolytic solution storage tank 20, the decomposition of the persulphuric acid in the sulphuric acid solution stored in the electrolytic solution storage tank 20 is promoted, and the sulphuric acid solution is cooled by the cooler 53, which is the second cooling unit, to a proper temperature, and is then introduced into the electrolytic solution storage tank 20. The sulphuric acid solution introduced into the electrolytic solution storage tank 20 is transported to the electrolysis device 1 by the supply side of the first circulation line 11, the persulphuric acid is generated by the electrolysis, and the sulphuric acid solution is again transported to the electrolytic solution storage tank 20 by the return side of the first circulation line 11. The persulphuric acid is continuously generated by repeating this circulation in the electrolysis unit A.

The operation of this system can transport the sulphuric acid solution containing the persulphuric acid from the electrolysis unit A to the rapid heating unit B, the cleaning unit C, and the waste liquid storage unit D, and can then circulate to the electrolysis unit A, thereby continuously supplying the cleaning liquid at the high temperature containing the persulphuric acid at a high concentration to the cleaning device 40, which is the using side.

Moreover, when the cleaning is stopped upon the replacement of the electronic material substrate 100 in the cleaning device 40, the on-off valve 26 is closed and the on-off valve 31 is opened while the circulation and the electrolysis of the sulphuric acid solution in the electrolysis unit A continue. As a result, the sulphuric acid solution flows into the liquid transport line 30, and the sulphuric acid solution is transported to the waste liquid storage tank 50. On this occasion, the sulphuric acid solution has been heated by the rapid heater 23, the sulphuric acid solution containing the persulphuric acid at the high temperature is supplied to the waste liquid storage tank 50, and the temperature of the sulphuric acid solution and the concentration of the persulphuric acid in the waste liquid storage tank 50 are properly maintained. It should be noted that the power supply unit 25 may control the power supply quantity so that the heated temperature by the rapid heater 23 may be lower than that upon the cleaning on this occasion. Moreover, the liquid transport quantity of the sulphuric acid solution transported by the liquid transport line 22 may be reduced compared with that for the cleaning by adjusting the liquid transport pump 21. The residual organic matters and the like contained in the sulphuric acid solution stored before the switch of the circulation line are efficiently decomposed also by the supply of the sulphuric acid solution in the waste liquid storage tank 50.

As described before, even if the cleaning is stopped due to the replacement of the electronic material substrate or the like, a part of the solution containing the persulphuric acid is transported from the electrolysis unit A to the rapid heating unit B, the waste liquid storage unit D, and is returned to the electrolysis unit A while the circulation and electrolysis of the sulphuric acid solution is carried out in the electrolysis unit A, and, therefore, the residual organic matters and the like in the sulphuric acid solution stored in the waste liquid storage tank can be efficiently decomposed while the persulphuric acid is generated.

Though a description has not been given, a waste liquid line may be branched from and connected to the circulation flow line 45 on the upstream side of the waste liquid storage tank 50, and the sulphuric acid solution may not be transported to the waste liquid storage tank 50 and may be discharged to the outside of the system at an appropriate time.

It is possible to prevent that such as resist dope elements and other matters which are not oxidized and decomposed are accumulated in the solution in the system from being accumulated to a high concentration by the waste liquid line discharging a small quantity of the sulphuric acid at each appropriate time. This operation can be carried out by opening/closing control of a on-off valve provided on the circulation flow line and the waste liquid line.

Though, in the above description, when the liquid transport is carried out by the second circulation line, the third circulation line is stopped, a part of the sulphuric acid solution may be transported by the third cleaning line while the second circulation line carries out the liquid transport, thereby carrying out the cleaning.

Though the present invention is described based on the embodiment, the present invention is not limited to the contents of the embodiment, and may be properly modified as long as the modification does not depart from the present invention.

### DESCRIPTION OF THE REFERENCE NUMERAL

1 Electrolytic device

2 DC power supply

10 Gas/liquid separation tank

11 First circulation line

13 Cooler

20 Electrolytic solution storage tank

22 Liquid transport line

23 Rapid heater

26 On-off valve

27 Liquid transport line

30 Liquid transport line

31 On-off valve

40 Cleaning device

50 Decomposing tank

A Electrolysis unit

B Rapid heating unit

C Cleaning unit

D Waste liquid storage unit

1. A cleaning system comprising:
an electrolysis unit that electrolyses a sulphuric acid solution, thereby generating persulphuric acid;
an electrolytic solution storage unit that stores the electrolyzed sulphuric acid solution;
a first circulation line that circulates the sulphuric acid solution between the electrolysis unit and the electrolytic solution storage unit;
a cleaning device that cleans a material subject to cleaning by using the sulphuric acid solution containing the persulphuric acid;
a heating unit that heats the sulphuric acid solution used for the cleaning device;
a waste liquid storage unit that stores the sulphuric acid solution used by the cleaning device;
a second circulation line that transports the sulphuric acid solution electrolyzed by the electrolysis unit via the heating unit to the cleaning device, and circulates the sulphuric acid solution used by the cleaning device for the cleaning via the waste liquid storage unit; and
a third circulation line that transports the sulphuric acid solution electrolyzed by the electrolysis unit to the waste liquid storage unit without passing the sulphuric acid solution through the cleaning device, thereby circulating the sulphuric acid solution.

2. The cleaning system according to claim 1, wherein the third circulation line transports the sulphuric acid solution to the waste liquid storage unit via the heating unit.

3. The cleaning system according to claim 1, wherein the second circulation line and the third circulation line are selectively used in a predetermined sequence.

4. The cleaning system according to claim 1, wherein:
the second circulation line has a branch portion at which the third circulation line branches downstream of the heating unit; and
the second circulation line can stop the liquid transport from the branch portion to the cleaning device, and can carry out the liquid transport from the branch portion to the third circulation line.

5. The cleaning system according to claim 1, wherein the temperature of the sulphuric acid solution electrolyzed by the electrolysis unit is equal to or less than 80° C.;
the temperature of the sulphuric acid solution heated by the heating unit, and then used by the cleaning device is 150 to 220° C.; and
the temperature of the sulphuric acid solution stored in the waste liquid storage unit is 120 to 160° C.

6. The cleaning system according to claim 1, wherein the sulphuric acid concentration of the sulphuric acid solution is equal to or more than 85 mass %.

7. The cleaning system according to claim 1, comprising a first cooling unit that cools the sulphuric acid solution from the electrolytic solution storage unit to the electrolysis unit.

8. The cleaning system according to claim 1, comprising a second cooling unit that cools the sulphuric acid solution from the waste liquid storage unit to the electrolytic solution storage unit.

9. The cleaning system according to claim 1, wherein the cleaning device is a single-wafer cleaning device.

10. A cleaning method comprising:
electrolyzing a sulphuric acid solution while circulating the sulphuric acid solution during cleaning;
branching a part of the electrolyzed sulphuric acid solution;
heating the branched part of the sulphuric acid solution;
using the heated sulphuric acid solution for cleaning a material subject to cleaning;
storing thereafter the sulphuric acid solution, thereby decomposing the material subject to cleaning, which has moved into the sulphuric acid solution;
simultaneously circulating the stored sulphuric acid solution for the electrolysis;
circulating the sulphuric acid solution while electrolyzing the sulphuric acid solution when the cleaning is stopped;
simultaneously branching a part of the electrolyzed sulphuric acid solution, thereby supplying the branched part of the electrolyzed sulphuric acid solution to the stored sulphuric acid solution, and decomposing the material subject to cleaning which has moved into the sulphuric acid solution; and
circulating the stored sulphuric acid solution for the electrolysis.

11. The cleaning method according to claim 10, wherein the electrolyzed and branched sulphuric acid solution is heated, and then is fed to the stored sulphuric acid solution.

12. The cleaning system according to claim 2, wherein the second circulation line and the third circulation line are selectively used in a predetermined sequence.
